(19) United States
(12) Patent Application Publication
(10) Pub. No.: US 2009/0194805 A1
(43) Pub. Date: Aug. 6, 2009

(54) Non-Volatile Memory Device

(75) Inventors: Hee-Soo Kang, Gyeonggi-do (KR); Choong-Ho Lee, Gyeonggi-do (KR); Jong-Ho Lim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/362,930

(22) Filed: Jan. 30, 2009

(30) Foreign Application Priority Data
Jan. 31, 2008 (KR) 2008-10125

(51) Int. Cl. H01L 29/788

(52) U.S. Cl. 257/321; 257/E29.3

(57) ABSTRACT

A non-volatile memory device includes a substrate, an active region, an isolation layer, a tunnel insulation layer, a floating gate, a dielectric layer and a control gate. The active region includes an upper active region having a first width, and a lower active region beneath the upper active region and having a second width substantially larger than the first width. The isolation layer is adjacent to the active region. The tunnel insulation layer is on the upper active region. The floating gate is on the tunnel insulation layer and has a third width substantially larger than the first width. The dielectric layer is on the floating layer. The control gate is on the dielectric layer.

### RELATED APPLICATION

This application claims priority under 35 U.S.C. §119 to Korean Patent Application No. 2008-10125, filed on Jan. 31, 2008 in the Korean Intellectual Property Office (KIPO), the disclosure of which is herein incorporated by reference in its entirety.

### BACKGROUND

1. Field

Example embodiments relate to a non-volatile memory device and a method of manufacturing the non-volatile memory device. More particularly, example embodiments relate to a non-volatile memory device including a dielectric layer having a high dielectric constant and a method of manufacturing the non-volatile memory device.

2. Description of the Related Art

Memory devices may be divided into volatile memory devices and non-volatile memory devices. Generally, a volatile memory device has high input and output operation speeds; however, the volatile memory device loses data over time. The non-volatile memory device has low input and output operation speeds; however, the non-volatile memory device may store data for a long time. Among the non-volatile memory devices, demand for electrically erasable programmable read-only memory (EEPROM) devices and flash memory devices, in which data may be written or erased electrically, has increased.

From the point of view of circuits, flash memory devices may be divided into NAND flash memory devices and NOR flash memory devices. A NAND flash memory device has a plurality of cell transistors electrically connected in series to each other to form a unit string. A plurality of the unit strings are electrically connected in series to a bit line and a ground line. A NOR flash memory device has a plurality of cell transistors electrically connected in parallel to a bit line and a ground line. As the critical dimensions of the non-volatile memory devices have decreased, the NAND flash memory device has been used more widely than the NOR flash memory device, because operations in the NAND flash memory device may be performed according at the unit string level, and additional contacts between the cell transistors may not be needed.

Generally, a cell transistor of the non-volatile memory device has a stacked structure in which a tunnel insulation layer, a floating gate, a dielectric layer and a control gate are sequentially stacked.

Meanwhile, as the non-volatile memory devices have become more highly integrated, distances between adjacent floating gates have been reduced. Accordingly, interference between the adjacent floating gates may be generated so that original data stored in cells may be changed.

In order to reduce the interference between the adjacent floating gates, parasitic capacitance is needed to be reduced, and thus the areas facing each other between the adjacent floating gates is needed to be reduced.

However, when the areas facing each other between the adjacent floating gates are reduced, the areas of dielectric layers formed on the floating gates may also be reduced. When the effective area of a dielectric layer is reduced, the voltage may not be sufficiently transferred from a control gate to a floating gate, and thus a lot of the voltage may be lost. That is, the coupling ratio of the non-volatile memory device may be reduced.

Particularly, the coupling ratio of a non-volatile memory device may be represented by the following Equation 1.

R=C_{dielectric}/(C_{dielectric}+Cₜₒ) [Equation 1]

Here, C_{dielectric} represents the capacitance of a dielectric layer, and Cₜₒ represents the capacitance of a tunnel insulation layer.

As can be seen from Equation 1, when the capacitance of the dielectric layer is increased or the capacitance of the tunnel insulation layer is reduced, the coupling ratio may be increased. However, when the effective area of the dielectric layer on a floating gate is reduced, the capacitance of the dielectric layer may also be reduced, and thus the coupling ratio may be reduced.

When the area of the tunnel insulation layer contacting the floating gate is reduced, interference between the adjacent floating gates may be generated because lower portions of the floating gates may be exposed.

### SUMMARY

Example embodiments provide a non-volatile memory device having an increased coupling ratio and/or reduced interference between adjacent cell transistors.

Further embodiments provide methods of manufacturing a non-volatile memory device having an increased coupling ratio and/or reduced interference between the adjacent cell transistors.

Some further embodiments provide a memory apparatus including a non-volatile memory device having an increased coupling ratio and/or reduced interference between the adjacent cell transistors.

According to some example embodiments, a non-volatile memory device includes a substrate, an active region, an isolation layer, a tunnel insulation layer, a floating gate, a dielectric layer and a control gate. The active region includes an upper active region having a first width, and a lower active region formed under the upper active region and having a second width substantially larger than the first width. The isolation layer is formed adjacent to the active region. The tunnel insulation layer is formed on the upper active region. The floating gate is formed on the tunnel insulation layer and has a third width substantially larger than the first width. The dielectric layer is formed on the floating layer. The control gate is formed on the dielectric layer.

In some example embodiments, the thickness of the upper active region and the thickness of the lower active region may have a ratio of about 0.05:1 to about 0.5:1.

In some example embodiments, the isolation layer may include a first isolation layer and a second isolation layer. The first isolation layer may be formed from the floating gate to the lower active region. The second isolation layer may be formed from a surface of the substrate to the upper active region and disposed on a sidewall of the upper active region between the first isolation layer and the upper active region. For example, an tipper face of the floating gate opposite the substrate and an upper face of the first isolation layer opposite the substrate may be disposed at substantially the same level. Alternatively, an upper face of the floating gate may be disposed at a level substantially higher than that of the first isolation layer. A difference between the first width and the second width may correspond to the thickness of the second isolation layer.

In some example embodiments, the dielectric layer may include tantalum oxide (Ta₂O₅), titanium oxide (TiO₂), hafnium oxide (HfO₂), zirconium oxide (ZrO₂), hafnium silicate (HfSiₓO_{y}), zirconium silicate (ZrSiₓO_{y}), hafnium silicon oxynitride (HfSiₓO_{y}N_{z}), zirconium silicon oxynitride (ZrSiₓO_{y}N_{z}), aluminum oxide (Al₂O₃), aluminum oxynitride (AlₓO_{y}N_{z}), hafnium aluminate (HfAlₓO_{y}), yttrium oxide (Y₂O₃), niobium oxide (Nb₂O₅), cesium oxide (CeO₂), indium oxide (InO₃), lanthanum oxide (LaO₂), strontium titanate (SrTiO₃), lead titanate (PbTiO₃), strontium ruthenium oxide (SrRuO₃), and/or calcium ruthenium oxide (CaRuO₃). The dielectric layer may include a composite layer in which an oxide layer, a nitride layer and an oxide layer are sequentially stacked.

According to some example embodiments, there is provided a method of manufacturing a non-volatile memory device. A hard mask partially exposing a surface of a substrate is formed on the substrate. The substrate is etched using the hard mask as an etching mask to form a preliminary trench. The substrate having the preliminary trench is oxidized to form an oxide layer on a sidewall and the bottom of the preliminary trench to a predetermined depth. The oxide layer and the substrate having the preliminary trench is etched using the hard mask as an etching mask to form a trench. An insulating material is deposited in the trench to form an isolation layer, so that an active region including an upper active region having a first width and a lower active region having a second width substantially larger than the first width under the upper active region is defined. A tunnel insulation layer, a floating gate and a control gate are sequentially formed on the substrate between the isolation layers.

In some example embodiments, the hard mask may include a pad oxide layer pattern and a silicon nitride layer pattern.

In some example embodiments, the oxide layer may be formed by a radical oxidizing process.

In some example embodiments, the first width of the upper active region may be determined by the thickness of the oxide layer. The thickness of the upper active region may be determined by the depth of the preliminary trench.

In some example embodiments, the thickness of the upper active region and the thickness of the lower active region may have a ratio of about 0.05:1 to about 0.5:1.

In some example embodiments, forming the isolation layer may include forming a preliminary isolation layer including an insulating material in the trench and on the hard mask; and removing the preliminary isolation layer to expose an upper face of the hard mask.

In some example embodiments, a tunnel insulation layer may be formed on the substrate exposed between the isolation layers after removing the hard mask.

In some example embodiments, forming the floating gate may include forming a preliminary floating gate layer on the tunnel insulation layer and the isolation layer; and removing the preliminary floating gate layer to expose an upper face of the isolation layer.

In some example embodiments, the dielectric layer may be formed using a material having a high dielectric constant. The dielectric layer may include a composite layer in which an oxide layer, a nitride layer and an oxide layer are sequentially stacked.

According to some example embodiments, a memory device includes a memory array and a control circuit. The memory array includes a plurality of memory cells including a substrate; an active region in the substrate, the active region including an tipper active region having a first width and a lower active region having a second width substantially larger than the first width under the upper active region; an isolation layer adjacent to the active region; a tunnel insulation layer on the upper active region; a floating gate on the upper active region of the active region, the floating gate having a third width substantially larger than the first width; a dielectric layer on the floating gate; and a control gate on the dielectric layer. The control circuit writes data in the memory array or reads data from the memory array.

In some example embodiments, the memory array may include a NAND structure. For example, the memory array may include a ground select line and a string select line disposed at edges of the memory cells, respectively; and a common source line at an outer region of the ground select line and adjacent to the ground select line with respect to the memory cells. The memory device may further include an insulating interlayer covering the common source line, the ground select line, the string select line and the memory cell, and a contact adjacent to the string select line and formed through the insulating interlayer.

In some example embodiments, the memory array may include a NOR structure.

According to some example embodiments, a memory system includes a memory device, a control circuit and a controller. The memory device includes a memory array including a plurality of memory cells including a substrate; an active region in the substrate, the active region including an upper active region having a first width and a lower active region having a second width substantially larger than the first width under the upper active region; an isolation layer adjacent to the active region; a tunnel insulation layer on the upper active region; a floating gate on the upper active region of the active region, the floating gate having a third width substantially larger than the first width; a dielectric layer on the floating gate; and a control gate on the dielectric layer. The control circuit writes data in the memory array or reads data from the memory array. The controller controls the memory device.

In some example embodiments, the memory system may further include a card, and the memory device and the controller may be built into the card.

In some example embodiments, the memory system may further include a decoder decoding data from the memory device. The memory system may further include a display member showing the decoded data.

In some example embodiments, the controller may be connected to a host system.

According to some example embodiments, a process system includes a central processing unit (CPU) and a memory unit connected to the CPU. The memory unit includes a memory device, a control circuit and a controller. The memory device includes a memory array including a plurality of memory cells including a substrate; an active region in the substrate, the active region including an upper active region having a first width and a lower active region having a second width substantially larger than the first width under the upper active region; an isolation layer adjacent to the active region; a tunnel insulation layer on the upper active region; a floating gate on the upper active region of the active region, the floating gate having a third width substantially larger than the first width; a dielectric layer on the floating gate; and a control gate on the dielectric layer. The control circuit writes data in the memory array or reads data from the memory array. The controller controls the memory device.

According to some example embodiments, the modular memory apparatus includes a supporting unit, a memory unit on the supporting unit and an electric connector on the supporting unit. The electric connector is connected to the memory unit. The memory unit includes a memory device, a control circuit and a controller. The memory device includes a memory array including a plurality of memory cells including a substrate; an active region in the substrate, the active region including an upper active region having a first width and a lower active region having a second width substantially larger than the first width under the upper active region; an isolation layer adjacent to the active region; a tunnel insulation layer on the upper active region; a floating gate on the upper active region of the active region, the floating gate having a third width substantially larger than the first width; a dielectric layer on the floating gate; and a control gate on the dielectric layer. The control circuit writes data in the memory array or reads data from the memory array. The controller controls the memory device.

In some example embodiments, the modular memory apparatus may further include an interface unit on the supporting unit. The interface unit is connected to the memory unit and the electric connector.

According to the non-volatile memory device of the present invention, an active region includes an upper active region having a smaller width than that of a lower active region. A tunnel insulation layer, a floating gate, a dielectric layer and a control gate are formed on the active region. The width of the dielectric layer is larger than that of the tunnel insulation layer, and thus the non-volatile memory device may have a high coupling ratio. Additionally, since the non-volatile memory device includes the active region having the above structure, interference between adjacent floating gates may be reduced.

### BRIEF DESCRIPTION OF THE DRAWINGS

The accompanying drawings, which are included to provide a further understanding of the invention and are incorporated in and constitute a part of this application, illustrate certain embodiment(s) of the invention. In the drawings:

FIG. 1 is a cross-sectional view illustrating a non-volatile memory device in accordance with some example embodiments;

FIG. 2 is a cross-sectional view illustrating the dielectric layer of FIG. 1 in accordance with some example embodiments;

FIG. 3 is cross-sectional view illustrating a floating gate and the dielectric layer of FIG. 1 in accordance with other example embodiments;

FIG. 4 is a cross-sectional view illustrating the dielectric layer of FIG. 3 in accordance with some example embodiments;

FIGS. 5 to 12 are cross-sectional views illustrating a method of manufacturing a non-volatile memory device in accordance with some example embodiments;

FIG. 13 is a plan view illustrating a NAND flash memory in accordance with some example embodiments;

FIG. 14 is a cross-sectional view taken along a line I-I′ of FIG. 13;

FIG. 15 is a cross-sectional view taken along a line II-II′ of FIG. 13;

FIG. 16 is a plan view illustrating a NOR flash memory in accordance with some example embodiments;

FIG. 17 is a cross-sectional view illustrating the NOR flash memory in FIG. 16;

FIG. 18 is a block diagram illustrating the operation of a NAND flash memory in accordance with some example embodiments;

FIG. 19 is a block diagram illustrating an array part of the NAND flash memory in FIG. 18;

FIG. 20 is a block diagram illustrating the operation of a NOR flash memory in accordance with some example embodiments;

FIG. 21 is a block diagram illustrating a first bank (BK1) circuit pattern including row and column selectors, and peripheral circuits in FIG. 20;

FIG. 22 is a block diagram illustrating a memory system in accordance with some example embodiments;

FIG. 23 is a block diagram illustrating a memory system in accordance with other example embodiments;

FIG. 24 is a block diagram illustrating a memory system in accordance with other example embodiments;

FIG. 25 is a block diagram illustrating a memory system in accordance with other example embodiments;

FIG. 26 is a block diagram illustrating a memory system in accordance with other example embodiments;

FIG. 27 is a block diagram illustrating a memory system in accordance with other example embodiments;

FIG. 28 is a perspective view illustrating a modular memory device in accordance with example embodiments; and

FIG. 29 is a cross-sectional view illustrating the modular memory device in FIG. 28.

### DESCRIPTION OF THE EMBODIMENTS

Example embodiments are described more fully hereinafter with reference to the accompanying drawings. The invention may, however, be embodied in many different forms and should not be construed as limited to the example embodiments set forth herein. Rather, these example embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like or similar reference numerals refer to like or similar elements throughout. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of illustratively idealized example embodiments (and intermediate structures) of the invention. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

FIG. 1 is a cross-sectional view illustrating a non-volatile memory device in accordance with some example embodiments.

Referring to FIG. 1, the non-volatile memory device in accordance with some example embodiments includes a semiconductor substrate 105, an active region 110, an isolation layer 125, a tunnel insulation layer 130 on the semiconductor 105, a floating gate 135, a dielectric layer 140 and a control gate 145.

The semiconductor substrate 105 includes the active region 110 through which electric charges move, and the isolation layer 125 defining the active region 110.

The active region 110 includes an upper active region 115 and a lower active region 120 beneath the upper active region 115. The upper active region 115 has a width substantially different from that of the lower active region 120. For example, the upper active region 115 may have a first width d1, and the lower active region 120 may have a second width d2 substantially larger than the first width d1. The widths d1 and d2 are measured in a second direction substantially perpendicular to a first direction (i.e., into the plane of the illustration) in which the active region 110 extends. All other widths that will be illustrated later are also measured in the second direction.

In some example embodiments, the thickness ratio of the upper active region 115 to the lower active region 120 maybe about 0.05:1 to about 0.5:1. For example, the upper active region 115 may have a thickness of about 20 Å to about 1,500 Å.

The active region 110 has a structure in which the upper active region 115 and the lower active region 120 have widths substantially different from each other. The first width d1, the second width d2, and the thicknesses of the upper and lower active regions 115 and 120 may be modified by variables such as types or conditions of processes for forming the non-volatile memory devices, or types, thicknesses and materials of layers formed on the active region 110.

The isolation layer 125 is formed adjacent to the active region 110, thereby defining the active region 110. For example, the isolation layer 125 may separate adjacent active regions 110 from each other to define the active region 110.

In some example embodiments, the isolation layer 125 includes a first isolation layer 126 and a second isolation layer 127.

The first isolation layer 126 is formed on a sidewall of the floating gate 135, a sidewall of the tunnel insulation layer 130 and a sidewall of the lower active region 120. The first isolation layer 126 may separate adjacent floating gates 135 from each other as well as the adjacent active regions 110 from each other.

For example, the first isolation layer 126 may be formed by a shallow trench isolation (STI) process in which a trench (not shown) between the adjacent active regions 110 is filled with an insulating material. The first isolation layer 126 may extend in the first direction.

The second isolation layer 127 is formed on a sidewall of the upper active region 115. Particularly, the second isolation layer 127 may be formed between the sidewall of the first isolation layer 126 and the sidewall of the upper active region 115. That is, the second isolation layer 127 is formed on the sidewall of the upper active region 115 having a width substantially smaller than that of the lower active region 120.

In some example embodiments, a width difference between the upper active region 115 and the lower active region 120 maybe generated according to the thickness of the second isolation layer 127. For example, when the second isolation layer 127 has a large thickness, the first width d1 may be small. When the second isolation layer 127 has a small thickness, the first width d1 may be large. Accordingly, the first width d1 may be determined by the thickness of the second isolation layer 127.

A tunnel insulation layer 130 is formed on the active region 110. For example, the tunnel insulation layer 130 may be formed on the upper active region 115 of the active region 110 and the second isolation layer 127. Accordingly, the width and the area of the tunnel insulation layer 130 making contact with the active region 110 may be reduced by the second isolation layer 127. The tunnel insulation layer 130 may be formed by thermally oxidizing the semiconductor substrate 105. Alternatively, the tunnel insulation layer 130 may be formed by depositing an oxide on the upper active region 115 of the active region 110.

The floating gate 135 is formed on the tunnel insulation layer 130. The floating gate 135 may include a material that can hold or emit electric charges. For example, the floating gate 135 may include polysilicon. When the floating gate 135 has a thickness less than about 150 Å, the ability to hold the electric charges of the floating gate 135 may be reduced, and patterning the floating gate 135 may not be easy. When the floating gate 135 has a thickness greater than about 300 Å, the parasitic capacitance between adjacent floating gates 135 may be increased. Thus, the floating gate 135 may have a thickness of about 150 Å to about 300 Å.

In some embodiments, the floating gate 135 may extend to a height relative to the substrate 105 that is higher than the isolation layer 125 adjacent thereto. That is, the floating gate 135 may have an upper face substantially higher than that of the first isolation layer 126. The upper portion of the floating gate 135 may protrude from the upper face of the first isolation layer 126.

The floating gate 135 may have a third width d3. For example, the third width d3 may be substantially larger than the first width d1 of the upper active region 115. That is, the floating gate 135 may have a width substantially larger than that of the upper active region 115.

The dielectric layer 140 is formed on the floating gate 135 and the isolation layer 125. The dielectric layer 140 may be formed by a chemical vapor deposition (CVD) process or an atomic layer deposition (ALD) process.

For example, the dielectric layer 140 may include a material having a high dielectric constant. The dielectric layer 140 may include a metal oxide having a high dielectric constant over about 10. The dielectric layer 140 may include tantalum oxide (Ta₂O₅), titanium oxide (TiO₂), hafnium oxide (HfO₂), zirconium oxide (ZrO₂), hafnium silicate (HfSiₓO_{y}), zirconium silicate (ZrSiₓO_{y}), hafnium silicon oxynitride (HfSiₓO_{y}N_{z}), zirconium silicon oxynitride (ZrSiₓO_{y}N_{z}), aluminum oxide (Al₂O₃), aluminum oxynitride (AlₓO_{y}N_{z}), hafnium aluminate (HfAlₓO_{y}), yttrium oxide (Y₂O₃), niobium oxide (Nb₂O₅), cesium oxide (CeO₂), indium oxide (InO₃), lanthanum oxide (LaO₂), strontium titanate (SrTiO₃), lead titanate (PbTiO₃), strontium ruthenium oxide (SrRuO₃), calcium ruthenium oxide (CaRuO₃), etc. These may be used alone or in a combination thereof.

In some example embodiments, the floating gate 135 may extend to a height relative to the substrate 105 that is higher than the first isolation layer 126, so that a portion of the dielectric layer 140 formed on the floating gate 136 may have a generally convex shape. Thus, a portion of the dielectric layer 140 making contact with the floating gate 135 may have an increased area compared, for example, with a floating gate that does not extend higher than the first isolation layer 126. In this case, the length of the area of the dielectric layer 140 making contact with the floating gate 135 in the second direction may based on the third width d3 and the thickness of the floating gate 135.

As described above, the coupling ratio of a non-volatile memory device may be calculated from the ratio of the capacitance of a dielectric layer with respect to a sum of capacitances of the dielectric layer and a tunnel insulation layer. Thus, when the capacitance of the dielectric layer is increased or when the capacitance of the tunnel insulation layer is reduced, the coupling ratio may be increased. That is, the coupling ratio may be calculated from the ratio of the width of the upper active region 115 corresponding to the floating gate 135 via the tunnel insulation layer 130 with respect to the floating gate 135 and the width of the floating gate 135 corresponding to the control gate 145 via the dielectric layer 140. In some example embodiments, the third width d3 corresponds to a portion of the floating gate 135 making contact with the dielectric layer 140. The first width d1 corresponds to a portion of the upper active region 115 making contact with the tunnel insulation layer 130. Thus, the non-volatile memory device has the first width d1 that is reduced by the second isolation layer 127, so that the coupling ratio of the non-volatile memory device may be improved. Accordingly, the non-volatile memory device may have improved programming and erasing operation characteristics.

Also, interference between the adjacent floating gates 135 may be reduced because the first isolation layer 126 is disposed between the adjacent floating gates 135. Further, interference between the adjacent floating gates 135 through the tunnel insulation layer 130 may be reduced or blocked by the lower active region 120 of the active region 110 having a large width. Accordingly, electrical failures generated by the interference between the adjacent floating gates 135 maybe reduced.

The control gate 145 is formed on the dielectric layer 140. For example, the control gate 145 may extend in the second direction that is perpendicular to the first direction in which the isolation layer 125 is extended.

The control gate 145 may include a metal nitride layer pattern having a work function of about 4.6 eV to about 5.2 eV. The control gate 145 may include tantalum nitride and/or titanium nitride. These may be used alone or a combination thereof. Alternatively, the control gate 145 may include other various materials.

When the control gate 145 includes a metal nitride layer pattern having such a high work function, the energy barrier between the control gate 145 and the dielectric layer 140 becomes high. Accordingly, a reverse tunneling in which electric charges move from the control gate 145 to the dielectric layer 140 may be reduced or prevented.

The control gate 145 may have a thickness of about 20 Å to about 1,000 Å. For example, the control gate 145 may have a thickness of about 100 Å to 300 Å.

The non-volatile memory device may have an increased coupling ratio because of the upper active region 115 having a reduced width. The interference generated by parasitic capacitance between the adjacent floating gates 135 may also be reduced. Thus, the programming or erasing window margin may be increased, so that electrical characteristics of the non-volatile memory device such as multi-level cell (MLC) operations by which a plurality of data may be read or written in one cell may be improved.

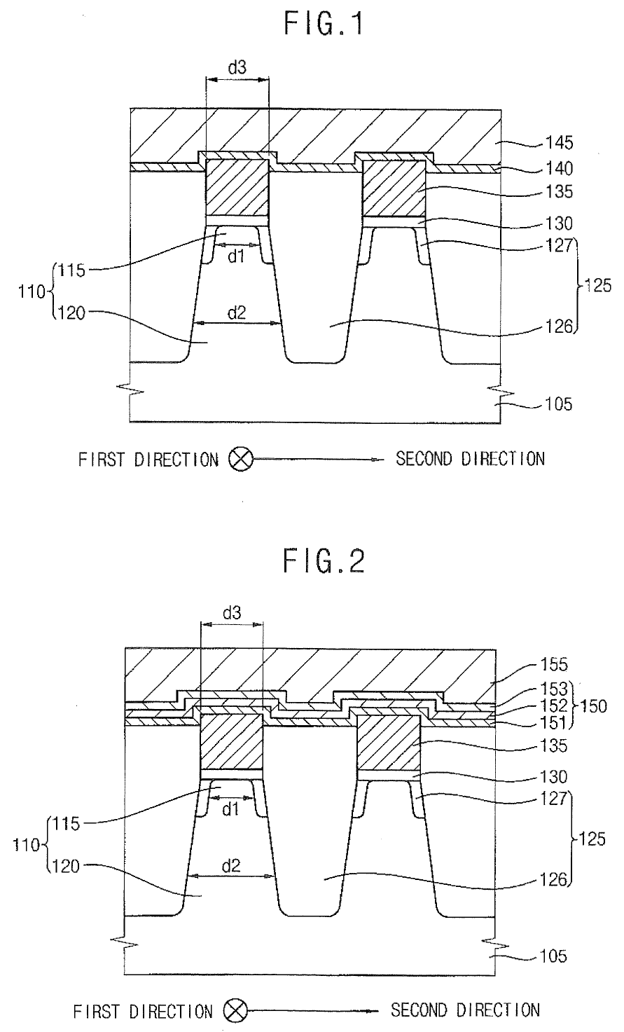

FIG. 2 is a cross-sectional view illustrating a non-volatile memory device in accordance with other example embodiments. The non-volatile memory device in FIG. 2 has a structure substantially the same as that of the non-volatile memory device illustrated with reference to FIG. 1, except for a dielectric layer. Accordingly, like numerals refer to like elements and repeated descriptions of those elements are omitted herein.

A dielectric layer 150 is formed on the floating gate 135. The dielectric layer may have a composite layer structure in which an oxide layer 151, a nitride layer 152 and an oxide layer 151 are sequentially stacked. That is, the dielectric layer 150 may have a stacked structure in which an oxide, silicon nitride and silicon oxide are sequentially stacked.

A control gate 155 is formed on the dielectric layer 150. For example, the control gate 155 may include a metal nitride.

When the dielectric layer 150 has the above stacked structure, a Fermi level pinning phenomenon due to a metal oxide having a high dielectric constant may be avoided. Thus, the control gate 155 may include polysilicon as well as a metal nitride.

In some example embodiments, the width of a portion of the floating gate 135 corresponding to the control gate 155 via the dielectric layer 150 in the second direction is larger than that of a portion of the floating gate 135 corresponding to the active region 110 via the tunnel insulation layer 130 in the second direction. That is, the third width d3 is larger than the first width d1. Thus, a coupling ratio calculated from the ratio of the third width d3 with respect to the first width d1 may be increased. Accordingly, the nonvolatile memory device 100 may have improved electrical and operational characteristics.

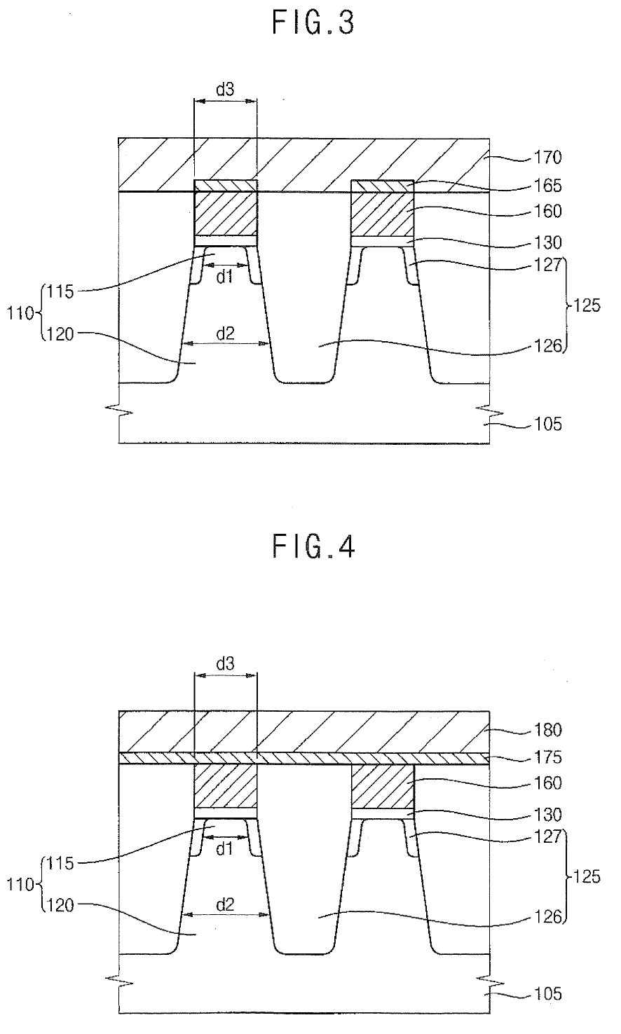

FIG. 3 is cross-sectional view illustrating a non-volatile memory device in accordance with still other example embodiments, and FIG. 4 is a cross-sectional view illustrating a non-volatile memory device in accordance with yet other example embodiments. The non-volatile memory devices in FIGS. 3 and 4 have structures substantially the same as that of the non-volatile memory device illustrated with reference to FIG. 1, except for a floating gate and a dielectric layer. Accordingly, like numerals refer to like elements and repeated descriptions of those elements are omitted herein.

Referring to FIGS. 3 and 4, a floating gate 160 is formed on the tunnel insulation layer 130 between the isolation layers 125. In some example embodiments, an upper face of the floating gate 160 is disposed at a level substantially the same as that of the first isolation layer 126. That is, when a plurality of the floating gates 160 are formed, the floating gates 160 may not have surfaces facing each other above the isolation layer 125. Thus, interference between the adjacent floating gates 160 may be reduced. Accordingly parasitic capacitance between the adjacent floating gates 160 may be reduced so that the non-volatile memory device may have improved electrical characteristics.

Referring now to FIG. 3, a dielectric layer pattern 165 is formed on the floating gate 160. A control gate 170 is formed on the dielectric layer pattern 165 and the first isolation layer 126. Referring now to FIG. 4, a dielectric layer 175 is formed on the floating gate 160 and the first isolation layer 126. A control gate 180 is formed on the dielectric layer 175.

The dielectric layer pattern 165 and the dielectric layer 175 may include a material having a high dielectric constant. For example, the dielectric layer pattern 165 and the dielectric layer 175 may include tantalum oxide (Ta₂O₅), titanium oxide (TiO₂), hafnium oxide (HfO₂), zirconium oxide (ZrO₂), etc. These may be used alone or in a combination thereof. Alternatively, the dielectric layer pattern 165 and the dielectric layer 175 may include a composite layer structure in which an oxide, nitride and oxide are sequentially stacked.

When the dielectric layer pattern 165 and the dielectric layer 175 include the material having the high dielectric constant, the control gates 170 and 180 may have a metal nitride having a high work function.

When the floating gate 160 is disposed at the same level of the isolation layer 125 or at a level below the isolation layer 125, interference between the adjacent floating gates 160 may be sufficiently reduced. Additionally, the first width d1 of the upper active region 115 of the active region 110 may be reduced, so that the coupling ratio of the non-volatile memory device may be improved.

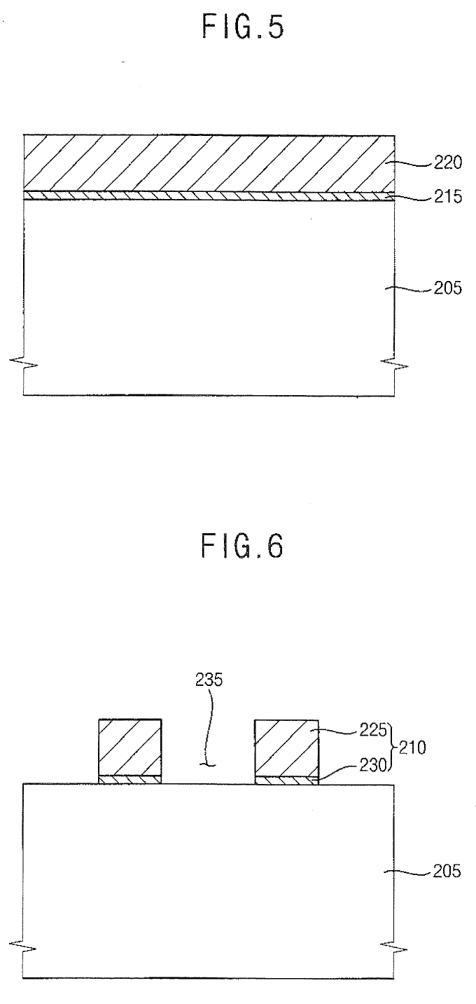

FIGS. 5 to 12 are cross-sectional views illustrating methods of manufacturing non-volatile memory devices in accordance with some example embodiments.

Referring to FIGS. 5 and 6, a hard mask 210 is formed on a semiconductor substrate 205.

Particularly, the semiconductor substrate 205 is provided. The semiconductor substrate 205 may include a silicon substrate.

A pad oxide layer 215 and a silicon nitride layer 220 are formed on the semiconductor substrate 205 for forming the hard mask 210. The pad oxide layer 215 may reduce stress between the semiconductor substrate 205 and the silicon nitride layer 220 when the silicon nitride layer 220 serving as an etching mask during an etching process is formed on the semiconductor substrate 205 including silicon.

The silicon nitride layer 220 and the pad oxide layer 215 are sequentially patterned to form the hard mask 210. That is, the silicon nitride layer 220 and the pad oxide layer 215 are sequentially patterned to form a silicon nitride layer pattern 225 and a pad oxide layer pattern 230. When the hard mask 210 is formed, an opening 235 partially exposing the semiconductor substrate 205 is formed.

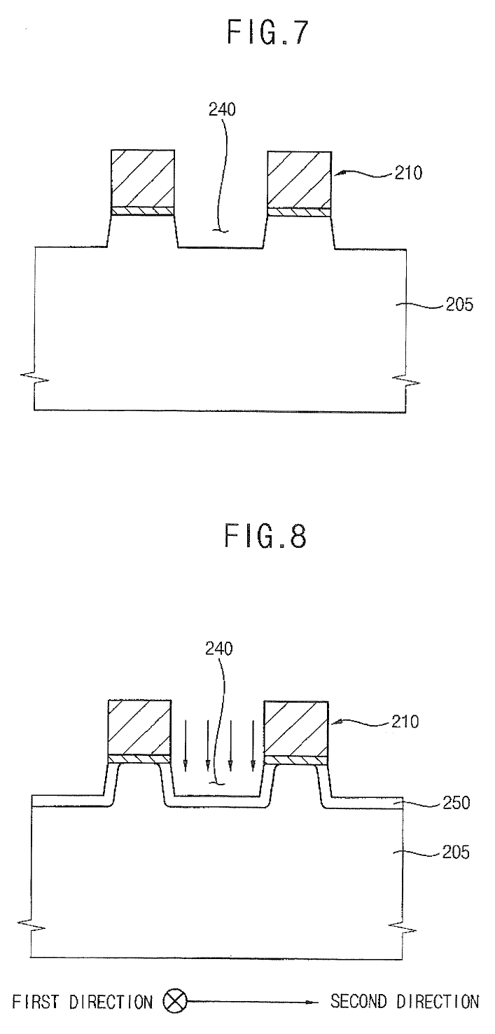

Referring to FIG. 7, a portion of the semiconductor substrate 205 exposed by the opening 235 is etched to a predetermined depth to form a preliminary trench 240. For example, the preliminary trench 240 may have a depth of about 20 Å to about 1,500 Å. That is, the semiconductor substrate 205 exposed by the opening 235 is etched to a depth of about 20 Å to about 1,500 Å.

The preliminary trench 240 may have various depths. The depth of the preliminary trench 240 may be changed according to a height of an upper active region described later.

Referring to FIG. 8, a bottom and a sidewall of the preliminary trench 240 are oxidized to form an oxide layer 250.

The oxide layer 250 may be formed by a radical oxidation process. The radical oxidation process may include providing a reaction gas including oxygen gas and hydrogen gas into a chamber, and exciting the reaction gas. Electric power of about 1,000 W to about 5,000 W is applied to the chamber under a pressure of about 1 mTorr to about 10 Torr in order to excite the reaction gas to a plasma state.

Oxygen radicals have kinetic energy substantially larger than that of oxygen gas and activation energy substantially smaller than that of oxygen gas, and thus an oxidation reaction may occur at a temperature of about 350° C to about 650° C., which is lower than that of the conventional wet or dry oxidation reactions occurring at a temperature of about 800° C. Also, an oxide layer obtained by the radical oxidation process may have a thickness substantially smaller than that of an oxide layer obtained by the conventional oxidation process.

The reaction plasma may be generated in a reaction chamber or provided from a remote plasma generator connected to the reaction chamber. For example, the reaction gas may be provided to the reaction chamber and radio frequency (RF) energy may be applied to the reaction chamber to form the reaction plasma. Alternatively, the reaction plasma may be generated by applying microwave energy to the reaction gas provided through the remote plasma generator.

The reaction gas may further include an inert gas serving as a plasma ignition gas. For example, the reaction gas may include an inert gas such as argon gas, nitrogen gas or helium gas in order to ignite and maintain the ignition of the plasma.

As illustrated above, the oxide layer 250 may be formed on the bottom and the sidewall of the preliminary trench 240 to a predetermined thickness by the radical oxidation process. That is, a portion of the semiconductor substrate 205 exposed by the preliminary trench 240 may be oxidized to be converted into the oxide layer 250.

The oxide layer 250 cures a top surface of the semiconductor substrate 205 damaged by an etching process for forming the preliminary trench 240 and forms an edge portion of an active region to have a rounded shape. When the edge portion of the active region has an angled shape or a pointed shape, electric charges or electrical forces may be concentrated at the angled or pointed edge. The radical oxidation process may form the edge portion to have a rounded shape, so that electric charges or electrical forces may be less likely to become concentrated at the edge portion of the active region.

The width of the active region in a second direction perpendicular to a first direction (into the plane of the illustration) in which the active region extends may be determined by the thickness of the oxide layer 250. When the oxide layer 250 has a large thickness, the width of the active region adjacent to the oxide layer 250 may be reduced. When the oxide layer 250 has a small thickness, the width of the active region adjacent to the oxide layer 250 may be increased. The thickness of the oxide layer 250 may be adjusted by controlling a process time of the radical oxidation process, or the quantity or the concentration of the reaction gas in the radical oxidation process, and thus the width of the active region may be controlled.

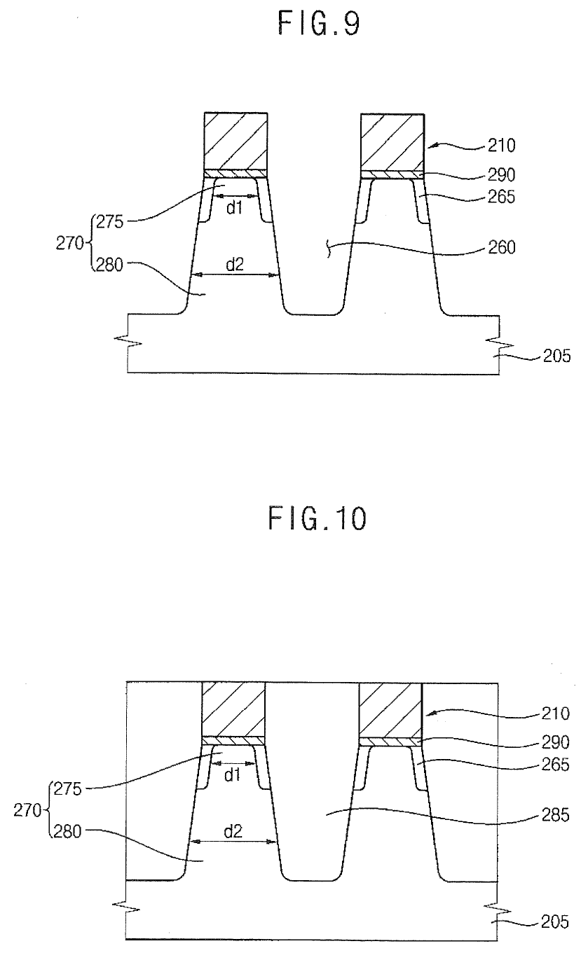

Referring to FIG. 9, a portion of the semiconductor substrate 205 exposed by the preliminary trench 240 is etched using the hard mask 210 as an etching mask. Particularly, the oxide layer 250 on the bottom of the preliminary trench 240 and the semiconductor substrate 205 thereunder are etched using the hard mask 210 as an etching mask.

A trench 260 is formed by the etching process. The oxide layer 250 is partially etched to form an oxide layer pattern 265. When a portion of the oxide layer 250 under the preliminary trench 240 is etched, a portion of the oxide layer 250 formed on the sidewall of the preliminary trench 240 remains. The remaining oxide layer 250 corresponds to the oxide layer pattern 265.

For example, the trench 260 may include a first portion and a second portion on the first portion, and the oxide layer pattern 265 is formed on a sidewall of the first portion of the trench 260 and is not formed on a sidewall of the second portion of the trench 260. For example, the depth ratio of the first portion to the second portion may be about 1:0.05 to about 1:0.5. The depth of the trench 260 may be varied.

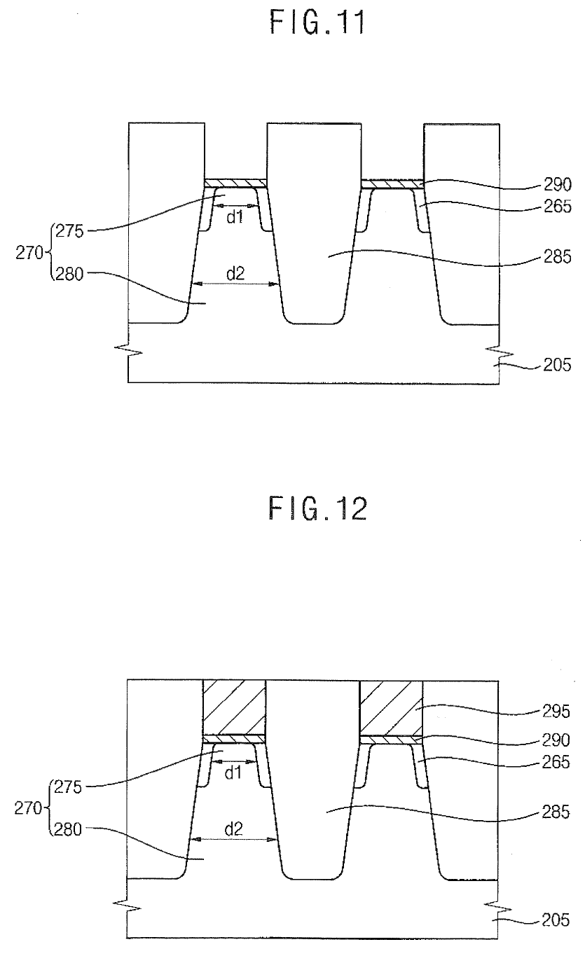

Referring to FIG. 10, the trench 260 is filled with an insulating material to form an isolation layer 285 to define an active region 270.

Particularly, the trench is filled up with an insulating material covering the hard mask 210, so that a preliminary isolation layer may be formed. The preliminary isolation layer may include an oxide having good gap-filling characteristics. For example, the preliminary isolation layer may include undoped silicate glass (USG), spin-on glass (SOG), borosilicate glass (BSG), phosphosilicate glass (PSG), borophosphosilicate glass (BPSG), flowable oxide (FOx), tetraethyl orthosilicate (TEOS), plasma-enhanced tetraethyl orthosilicate (PE-TEOS), high-density plasma chemical vapor deposition (HDP-CVD) oxide, etc.

An upper portion of the preliminary isolation layer is planarized until an upper face of the hard mask 210 is exposed, so that the isolation layer 285 may be formed. The planarization process may be performed by a chemical mechanical polishing (CMP) process and/or an etch-back process.

The isolation layer 285 defines the active region 270. In some example embodiments, the active region 270 includes an upper active region 275 and a lower active region 280. The upper active region 275 has a width substantially different from that of the lower active region 280 in the second direction. The upper active region 275 may make contact with the oxide layer pattern 265. The lower active region 280 may make contact with the isolation layer 285. The upper active region 275 may have a reduced width due to the oxide layer pattern 265. For example, the upper active region 275 may have a first width d1, and the lower active region 280 may have a second width d2 substantially larger than the first width d1.

The thickness ratio of the upper active region 275 to the lower active region 280 may be about 0.05:1 to about 0.5:1. For example, the upper active region 275 may have a thickness of about 20 Å to 1,500 Å. The upper active region 275 is formed to have a thickness corresponding to the depth of the trench 240.

The first width d1 of the upper active region 275 of the active region 270 is formed to be inversely proportional to the thickness of the oxide layer pattern 265. The thickness of the upper active region 275 is formed to be proportional to the depth of the preliminary trench 240. The upper active region 275 may be formed by modifying the conventional process.

The active region 270 may be divided into the upper active region 275 and the lower active region 280, which have widths different from each other. The active region 270 may have a winding shape including the upper active region 275 having a small width and the lower active region 280 having a large width.

Referring to FIGS. 11 and 12, a tunnel insulation layer 290 is formed on the active region 270 of the semiconductor substrate 205 after removing the hard mask 210 between the isolation layers 285. For example, the tunnel insulation layer 290 may be formed by a thermal oxidation process.

A floating gate 295 is formed on the tunnel insulation layer 290. For example, the floating gate 295 may be formed using polysilicon. Particularly, a preliminary floating gate layer filling the space between the isolation layers 285 is formed on the tunnel insulation layer 290 to cover the isolation layer 285. The preliminary floating gate layer may be planarized to form the floating gate 295 until an upper face of the isolation layer 285 is exposed.

For example, the planarization process may be performed until the floating gate 295 has an upper face at a level substantially the same as that of the isolation layer 285. Alternatively, the planarization process may be performed until the floating gate 295 has an upper face at a level substantially different from that of the isolation layer 285.

Referring to FIGS. 1 to 4, a dielectric layer having a high dielectric constant may be formed on the floating gate 295. Alternatively, a dielectric layer, in which an oxide, nitride and oxide are sequentially stacked, may be formed on the floating gate 295.

A control gate having a metal nitride may be formed on the dielectric layer.

A portion of the floating gate 295 making contact with the dielectric layer has a width larger than that of a portion of the floating gate 295 corresponding to the upper active region 275 via the tunnel insulation layer 290. Accordingly, the capacitance of the tunnel insulation layer 290 is reduced, so that the coupling ratio of the non-volatile memory device may be enhanced. Thus, the non-volatile memory device may have improved electrical characteristics.

Additionally, the floating gates 295 are separated from each other by the isolation layer 285, and interference between the adjacent floating gates 295 may be reduced by the lower active region 280 having a large width.

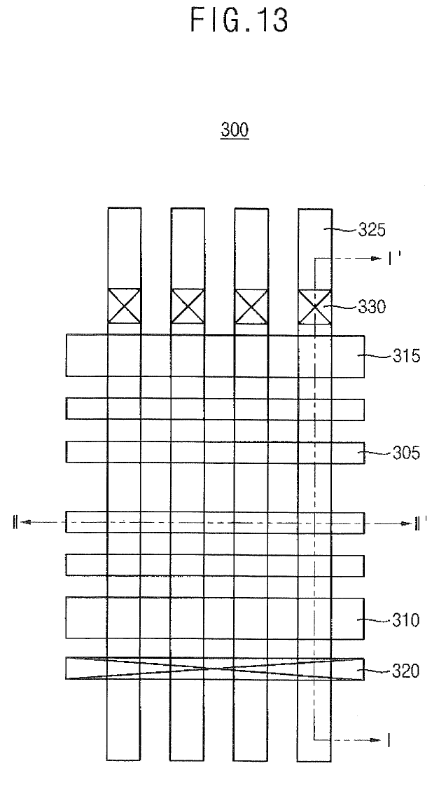

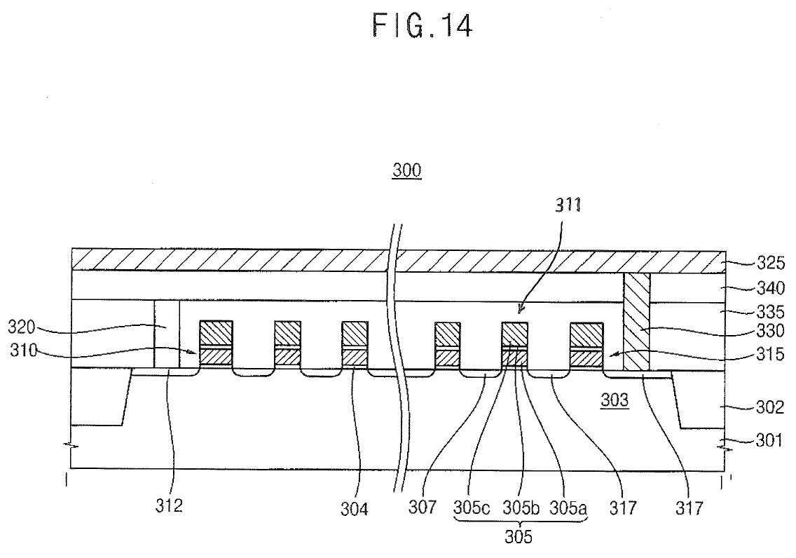

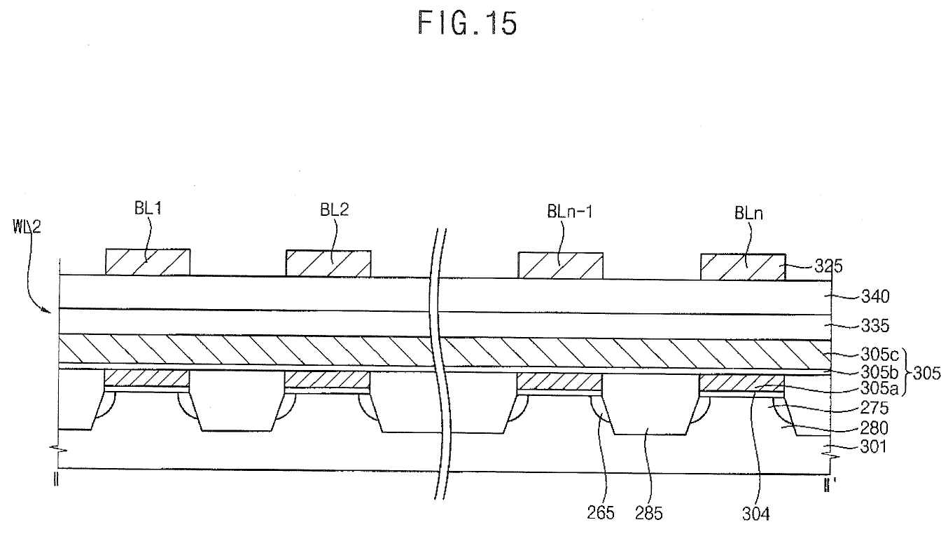

FIG. 13 is a plan view illustrating a NAND flash memory in accordance with some example embodiments. FIG. 14 is a cross-sectional view taken along a line I-I′ of FIG. 13, and FIG. 15 is a cross-sectional view taken along a line II-II′ of FIG. 13.

Referring to FIGS. 13 to 15, a NAND flash memory device 300 includes a plurality of word lines 305, a ground select line (GSL) 310, a string select line (SSL) 315 and a common source line (CSL) 320 on a substrate 301.

In some example embodiments, the flash memory device 300 has a string structure in which the plurality of word lines 305 are connected in series between a ground selection transistor (GST) 310 and a string selection transistor (SST) 315. For example, a plurality of the string structures may be connected to bit lines 325 to form one block. A drain region 317 of the SST 315 is electrically connected to the bit line 325 by a contact plug 330. A source region 312 of the GST 310 is electrically connected to the CSL 320. Further, all string structures in one block may share the CSL 320.

The NAND flash memory device 300 includes a plurality of memory cells 311, the GST 310, the SST 315 and the CSL 320 on the substrate 301. The flash memory device 300 has a string structure in which the plurality of word lines 305 are connected in series between the GST 310 and the SST 315.

Each of the memory cells 311 in FIGS. 14 and 15 includes a tunnel insulation layer pattern 304, a floating gate 305a, a dielectric layer pattern 305b and a control gate 305c on an active region 303.

Referring to FIG. 15, a portion of the floating gate 305a making contact with the dielectric layer pattern 305b has a width larger than that of a portion of the floating gate 305a corresponding to the upper active region 275 via the tunnel insulation layer pattern 304. Accordingly, the capacitance of the tunnel insulation layer pattern 304 is reduced, so that the coupling ratio of the non-volatile memory device may be enhanced. Thus, the non-volatile memory device may have improved electrical characteristics.

Additionally, the floating gates 305a are separated from each other by the isolation layer 285, and interference between the adjacent floating gates 305a may be reduced by the lower active region 280 having a large width.

Referring again to FIG. 14, a source 312 of the GST 310 is electrically connected to the CSL 320 to provide a reference electric potential for programming, erasing and reading of a memory device. A drain 317 of the SST 315 is electrically connected to the bit line 325 through the contact plug 330, which is formed through a first insulating interlayer 335 and a second insulating interlayer 340, to selectively provide an electric potential to the string structure.

The bit lines 325 are disposed along a direction substantially perpendicular to a longitudinal direction of the CSL 320. Each of the bit lines 325 is separated and electrically insulated by a third insulating interlayer (not shown).

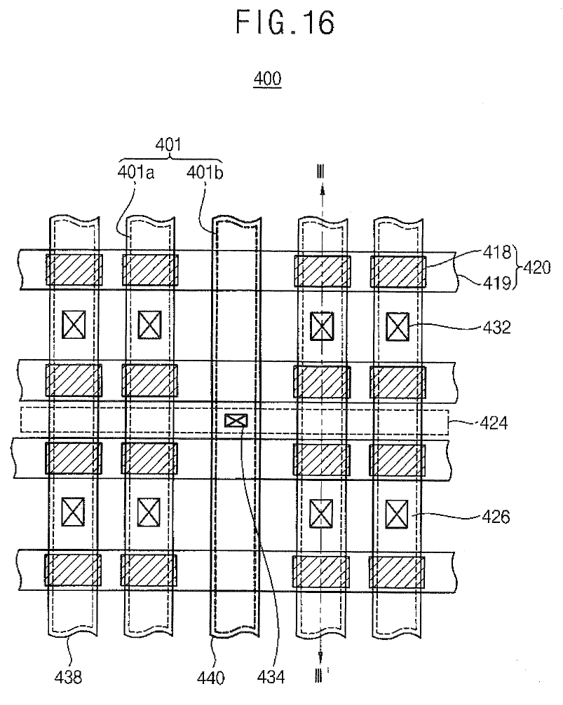

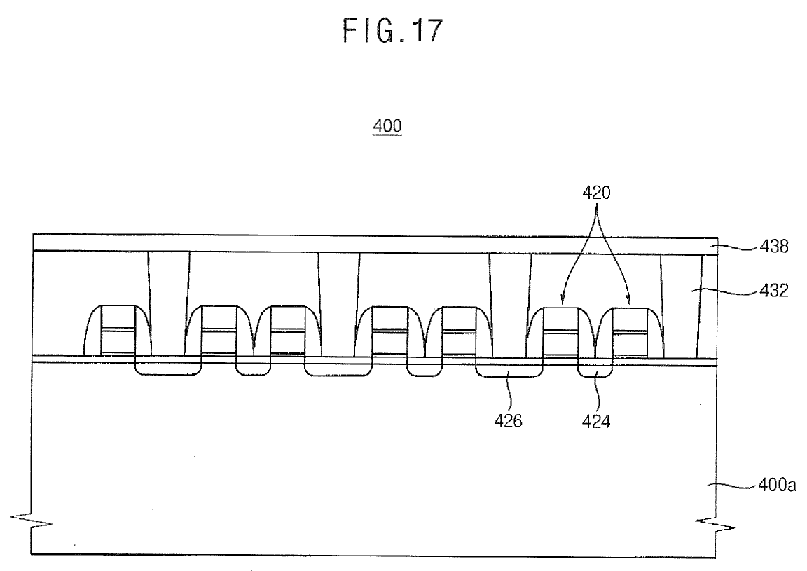

FIG. 16 is a plan view illustrating a NOR flash memory in accordance with some example embodiments. FIG. 17 is a cross-sectional view illustrating the NOR flash memory in FIG. 16 along line III-III′.

Referring to FIGS. 16 and 17, in the NOR flash memory 400, an isolation layer (not shown) is formed in a predetermined portion of a semiconductor substrate 400a to define an active region 401.

A plurality of word line patterns 420 are disposed across the active region 401. The word line patterns 420 include a floating gate 418, a gate dielectric interlayer (not shown) and a control gate 419, which are sequentially stacked.

A drain region 426 is disposed across the word line pattern 420 on a cell active region 401a of the active region 401. A bit line contact hole 432 is disposed on the drain region 426. A common source line 424 aligned to the word line pattern 420 is disposed along another side of the word line pattern 420. A common source contact hole 434 is formed on the CSL 424 to connect the CSL 424 to a common source contact line 440.

The bit line contact hole 432 is filled with a conductive material, so that a bit line contact plug is formed. An upper face of the bit line contact plug electrically makes contact with the bit line 438. The bit line 438 is formed on the cell active region 401a to cross the word line pattern 420.

The common source line contact hole 434 is filled with a conductive material, so that a source line contact plug is formed. An upper face of the source line contact plug electrically makes contact with a common source contact line 440. The common source contact line 440 is formed on the source active region 401b to be parallel to the bit line 438.

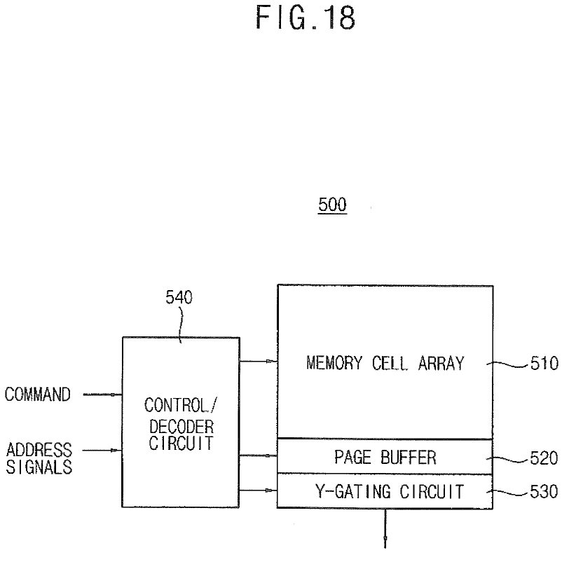

FIG. 18 is a block diagram illustrating a NAND flash memory in accordance with some example embodiments.

Referring to FIG. 18, the NAND flash memory 500 includes a memory cell array 510 having memory cells storing data, a page buffer block 520 controlling the operation of the array cell array 510, an Y-gating circuit 530 and/or a control/decoder circuit 540 controlling the operation of the memory cell array 510, the page buffer block 520 and the Y-gating circuit 530. The control/decoder circuit 540 receives command signals and address signals to generate control signals for controlling the memory cell array 510, the page buffer block 520 and the Y-gating circuit 530.

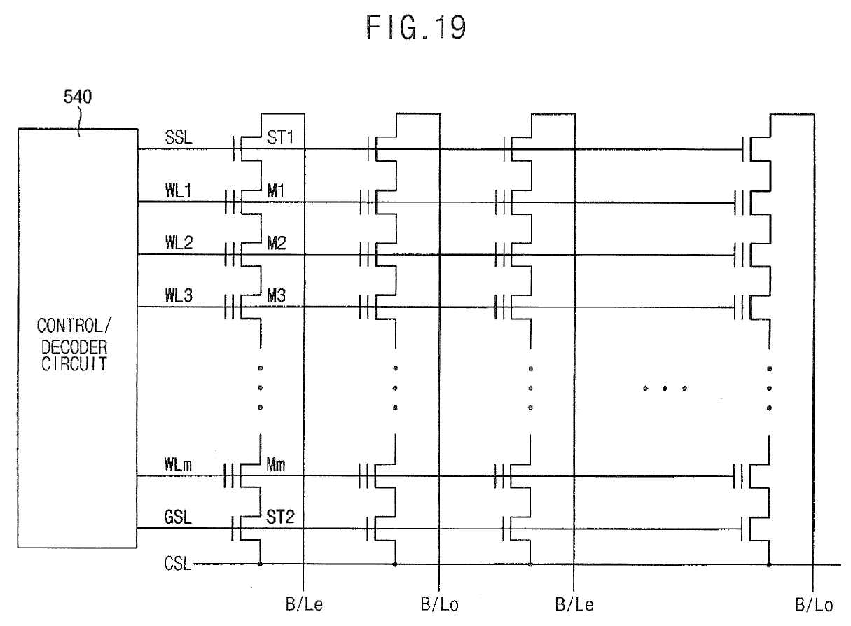

FIG. 19 is a block diagram illustrating an array part of the NAND flash memory in FIG. 18.

Referring to FIGS. 18 and 19, the memory cell array 510 includes a plurality of bit lines B/Lₑ and B/Lₒ. The Lₑ and Lₒ represent an even number and an odd number, respectively. The memory cell array 510 includes a plurality of cell strings, each of which is respectively connected to one of the bit lines B/Lₑ and B/Lₒ. Each cell string shown in FIG. 19 includes a string select transistor SST connected to the bit line, a ground select transistor GST connected to the common source line and a plurality of memory cells M₁, M₂, . . . , Mₙ (here, n is a natural number) connected to each other in series between the string select transistor SST and the ground select transistor GST. The plurality of memory cells M₁, M₂, . . . , Mₙ may be manufactured by the above embodiments. One or more strings may be connected to one bit line. Each of the bit lines may be connected to each of page buffers in the page buffer block 520, respectively.

The page buffer block 520 includes a plurality of page buffers which program or read data in the memory cell array based on control signals from the control/decoder circuit 540. The Y-gating circuit 530 selects the page buffer in the page buffer block 520 in order to input or output data based on control signals from the control/decoder circuit 540. Because the structure and the operation of the page buffer block 520, the Y-gating circuit 530 and the control/decoder circuit 540 are known to those skilled in the art, and the structures and operations of the elements will not be described in detail for the sake of brevity. An embodiment of a NAND flash memory device is disclosed in U.S. Pat. No. 7,042,770, and the embodiments of the present invention may be applied to the U.S. Pat. No. 7,042,770.

Further, applications of the embodiments of the present invention are not limited to the NAND flash memory in FIGS. 18 and 19. The embodiments of the present invention may be applied to architectures of cell arrays of other NAND flash memory devices.

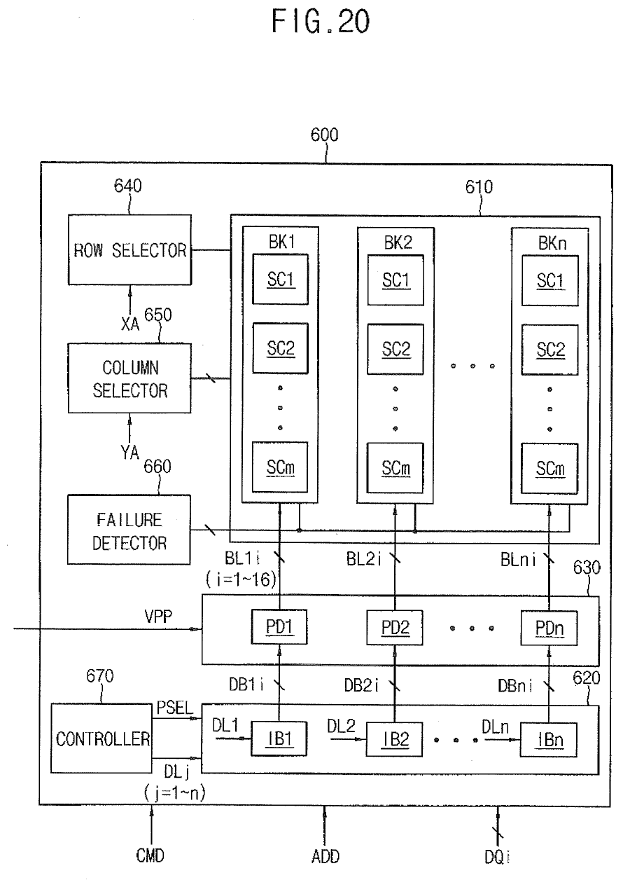

FIG. 20 is a block diagram illustrating the operation of a NOR flash memory in accordance with some example embodiments.

The NOR flash memory 600 includes a cell array 610, a row selector 640 and/or a column selector 650.

The cell array 610 includes a plurality of banks BK₁, BK₂, . . . , BKₙ. Each of the banks includes a plurality of sectors SC₁, SC₂, . . . , SCₘ, and forms an erasing unit. Each of the sectors includes a plurality of memory cells connected to the plurality of word lines and bit lines. Output lines and an output terminal are not illustrated in FIG. 20 in order to simply show the NOR flash memory 600.

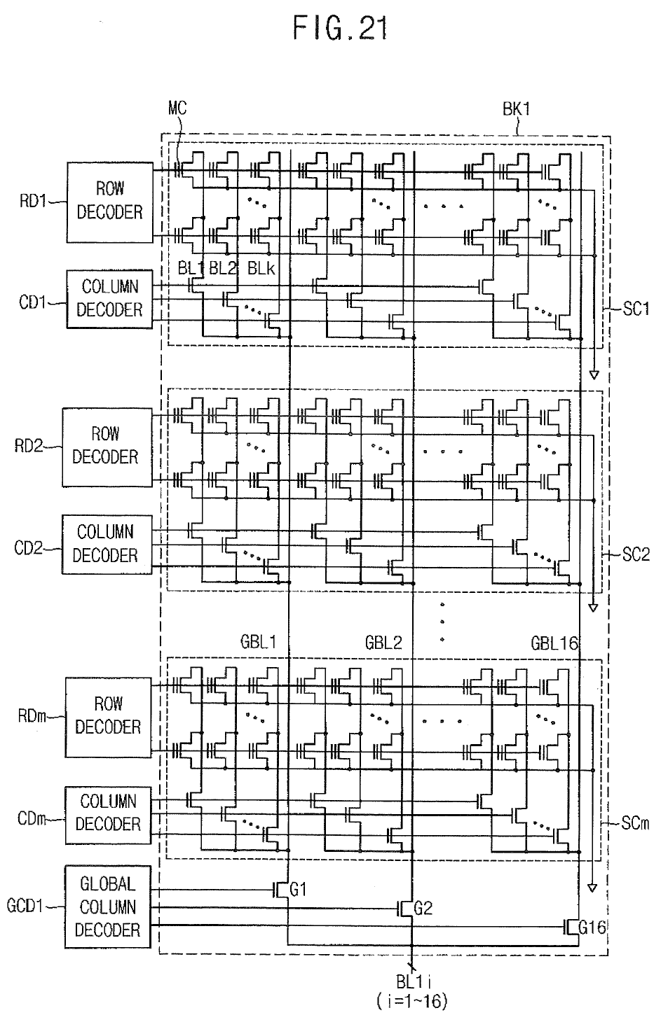

The row selector 640 selects one word line in response to a row address XA. The column selector 650 selects 16-bit lines of all banks in response to a column address YA. A structure and a method of the cell array, the row selector 640 and the column selector 650 will be described in detail with reference to FIG. 21.

The NOR flash memory 600 includes a data input buffer 620, a program driver and/or a controller 670. The data input buffer 620 simultaneously receives program 16-bit data in parallel, which is equal to the number of the banks. The program data are stored in a unit buffer IB₁, . . . , IBₙ of the input buffer in 16-bit data units. The unit buffer IB₁, . . . , IBₙ may be operated by controlling data latch signals DLⱼ (j is from 1 to n). When DL1 is at a high level, 16-bit data is simultaneously inputted to a first unit buffer IB₁. Then, the inputted data is temporarily stored in the first unit buffer IB₁. When a program select signal PSEL is at a high level, the data input buffer 420 outputs data stored in the unit buffer IB₁, . . . , IBₙ to the program driver 630.

The controller 670 provides the program select signal PSEL and the data latch signals DLⱼ to the data input buffer 620. The data input buffer 620 is selectively or continually controlled by the controller 670, so that the data input buffer 620 may receive the program data in 16-bit units, which is less than or equal to the number of the banks.

The program driver 630 simultaneously applies a program voltage to a bit line selected from bit line packets BL₁ᵢ, . . . , BLₙᵢ (i is from 1 to 16) in response to program data packets DL₁ᵢ, . . . , DLₙᵢ (i is 1 to 16) stored in the data input buffer 620. The program driver 630 includes unit drivers PD₁, . . . ,PDₙ corresponding to a unit buffer Pb₁, . . . , PBₙ. A high voltage Vpp is supplied to the program driver 630 from an external power source. The voltage Vpp is substantially higher than that of an internal power source. The high voltage Vpp from the external power source is used for applying a drain voltage and cell currents of a selected cell transistor in program operations. Alternatively, in the NOR memory device, it may be possible to supply the high voltage VPP internally by using a charge pump circuit (not shown) embedded in the NOR flash memory device.

The NOR flash memory 600 includes a failure detector 660. The failure detector 660 senses data stored in the cell array 610 and then detects a failure of programming by comparing the sensed data with program data stored in the data input buffer 620. The failure detector 660 is shared with all banks of the cell array 610.

The NOR flash memory 600 receives command signals CMD, address signals ADD, input/output data signals DQᵢ and high voltage signals Vpp. For example, the signals may be applied from a host device or a memory controller.

FIG. 21 is a block diagram illustrating a first bank (BK₁) circuit pattern including row and column selectors, and peripheral circuits in FIG. 20.

Referring to FIGS. 20 and 21, the row selector 640 includes a plurality of row decoders RD₁, . . . , RDₘ, and the column selector 650 includes a plurality of column decoders CD₁, . . . , CDₘ. Each of pairs of the row decoder and column decoder corresponds to the sectors SC₁, . . . , SCₘ, respectively. The column selector 650 includes a global column decoder GCD₁ corresponding to the first bank BK₁.

Referring to FIG. 21, in the first bank BK₁ including the sectors SC₁, . . . , SCₘ, each of which forms an erasing unit, the first sector SC₁ is connected to a row decoder RD₁ for driving a word line corresponding to the selected memory cell, and the first sector SC₁ is connected to the column decoder for selecting bit lines BL₁, . . . , BLₖ, which is specified as the global bit line (for example, GBL₁). The memory cells MC is manufactured in accordance with some example embodiments of the present invention. The global bit lines may include, for example, sixteen lines. Each of the global bit lines GBL₁, . . . , GBL₁₆ is linked with the bit lines through a column gate transistor in all sectors, respectively. The column gate transistor is controlled by a column decoder corresponding thereto. Other sectors are connected and disposed in the substantially same way as the first sector SC₁.

The global bit lines GBL₁, . . . , GBL₁₆ are lead from one bit line (for example, BL1ᵢ) of the bit line packets BL₁ᵢ, . . . , BLₙᵢ provided by the program driver. Each of selecting transistor G₁, . . . , G₁₆ is controlled by the global column decoder GCD1. Accordingly, the memory cell array has a structure in which local bit lines connect the memory cells formed along the columns, and global bit lines connect the local bit lines, respectively.

Because operations and methods of the NOR flash memory in FIGS. 20 and 21 are known to those skilled in the art, detailed descriptions are omitted. For example, an embodiment of a NOR flash memory device is disclosed in U.S. Pat. No. 7,072,214, and the embodiments of the present invention may be applied to the U.S. Pat. No. 7,072,214.

Also, applications of the present invention are not limited to the NOR memory flash memory in FIGS. 20 and 21. The example embodiments of the present invention may be applied to a cell array of various NOR flash memory devices.

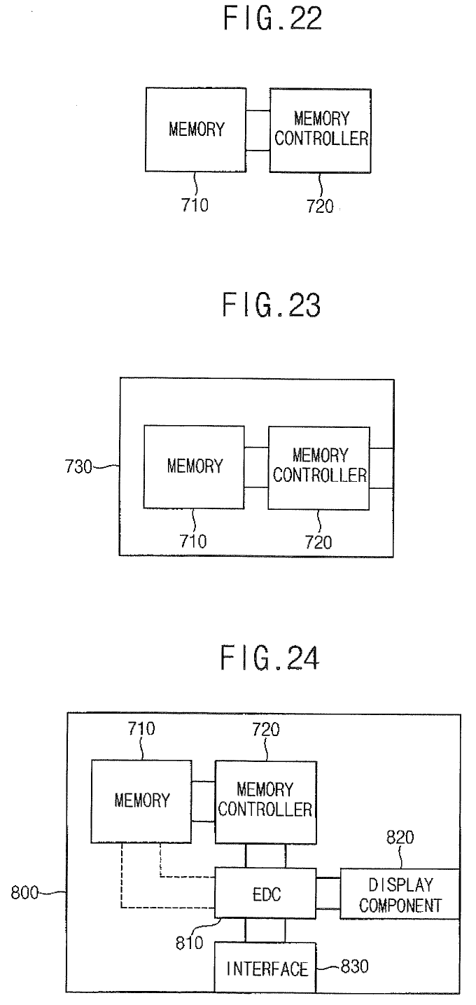

FIG. 22 is a block diagram illustrating a memory system in accordance with some example embodiments.

Referring to FIG. 22, a non-volatile memory device may include a memory 710 and a memory controller 720 connected to the memory 710. The memory 710 may include the NAND flash memory device or the NOR flash memory device described above. However, the memory 710 is not limited to the above memory devices and has a structure substantially the same as that manufactured in accordance with some example embodiments of the present invention. The memory controller 720 provides input signals controlling the operation of the memory 710. For example, in the NAND flash memory in FIGS. 18 and 19, the memory controller 730 may provide command signals CMD and address signals ADD. In the NOR flash memory in FIGS. 20 and 21, the memory controller 720 provides command signals CMD, address signals ADD, input/output data DQ and high voltage signals Vₚₚ. The memory controller 720 may control the memory 710 based on control signals applied thereto.

FIG. 23 is a block diagram illustrating a memory system in accordance with other example embodiments.

Referring to FIG. 23, an embodiment in accordance with FIG. 23 is substantially the same as that of FIG. 22 except that the memory 710 and the memory controller 720 are embodied in a memory card 730. The memory card 730 may include a card suitable for industrial standards used together with an electronic apparatus such as a digital camera, a personal computer, etc. The memory controller 720 may control the memory 710 based on control signals received from another external device.

FIG. 24 is a block diagram illustrating a memory system in accordance with other example embodiments.

Referring to FIG. 24, an embodiment in FIG. 24 shows a portable device 800. The portable device 800 may include an MP3 player, a video player or a combination apparatus of video and audio players. The portable device 800 may includes the memory 710, the memory controller 720, an encoder/decoder 810, a display component 820 and an interface 830.

Data such as audio data or video data may be inputted into the memory 710 or outputted from the memory 710 through the memory controller 720 by the encoder/decoder 810. The data such as audio data or video data may be inputted into the encoder/decoder 810 or outputted from the encoder/decoder 810 directly.

The encoder/decoder 810 encodes data for storage in the memory 710, For example, the encoder/decoder 810 may encode MP3 data for storing audio data in the memory 710. The encoder/decoder 810 may encode MPEG data for storing video data in the memory 710. Also, the encoder/decoder 810 includes multiple encoders for encoding different types of data according to different data formats. For example, the encoder/decoder 810 may include an MP3 encoder for audio data and an MPEG encoder for video data.

The encoder/decoder 810 may decode outputs from the memory 710. For example, the encoder/decoder 810 may perform MP3 decoding according to audio data from the memory 710. The encoder/decoder 810 may perform MPEG decoding according to video data from the memory 710. The encoder/decoder 810 may include an MP3 decoder for audio data or an MPEG decoder for video data.

EDC 810 may include only decoders. For example, already encoded data may be received by the EDC 810 and passed to the memory controller 720 and/or the memory 710.

The EDC 810 may receive data for encoding, or receive already encoded data, via the interface 830. The interface 830 may conform to a known standard (e.g., firewire, USB, etc.). The interface 830 may also include more than one interface. For example, interface 830 may include a firewire interface, a USB interface, etc. Data from the memory 710 may also be output via the interface 830.

The display components 820 may display data output from the memory, and/or decoded by the EDC 810, to a user. For example, the display components 820 may include a speaker jack for outputting audio data, a display screen for outputting video data, and/or etc.

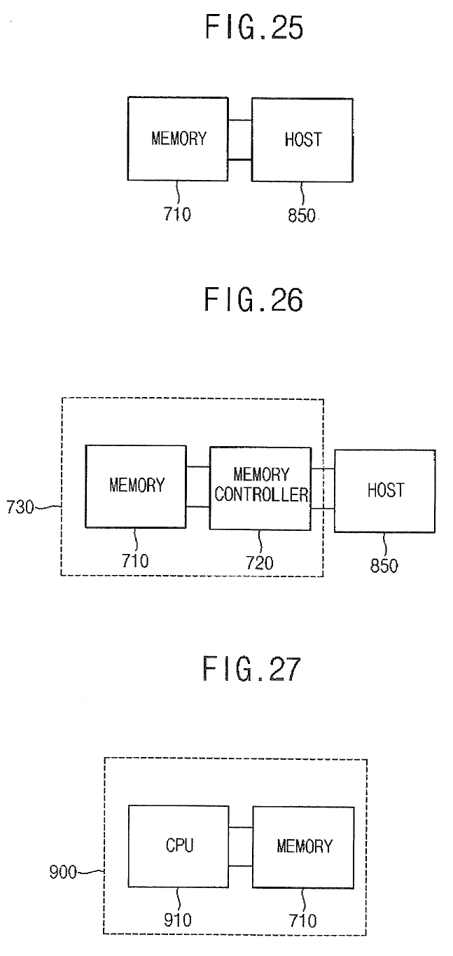

FIG. 25 is a block diagram illustrating a memory system in accordance with other example embodiments.

Referring to FIG. 25, the memory 710 may be connected to a host system 850. The examples of the host system 850 may include a processing system such as a personal computer, a digital camera, etc. The host system 850 applies input signals for controlling and operating the memory 710. For example, in the NAND flash memory in FIGS. 19 and 20, the host system 850 may apply command and address signals CMD and ADD. In the NOR flash memory in FIGS. 21 and 22, the host system 850 applies command signals CMD, address signals ADD, input/output data DQ and a high voltage signal Vₚₚ.

FIG. 26 is a block diagram illustrating a memory system in accordance with other example embodiments.

Referring to FIG. 26, the host system 850 may be connected to the memory card 730 in FIG. 23. In some example embodiments, the host system 850 provides control signals of the memory card 730. The memory controller 720 controls the operation of the memory 710.

FIG. 27 is a block diagram illustrating a memory system in accordance with other example embodiments.

Referring to FIG. 27, the memory 710 is connected to a central processing unit (CPU) 910 within a computer system 900. For example, the computer system 900 may include a personal computer, a personal data assistant, etc. The memory 710 may be connected to the CPU 910 directly or via a bus. Every element is not sufficiently illustrated in FIG. 27 for the sake of clarity.

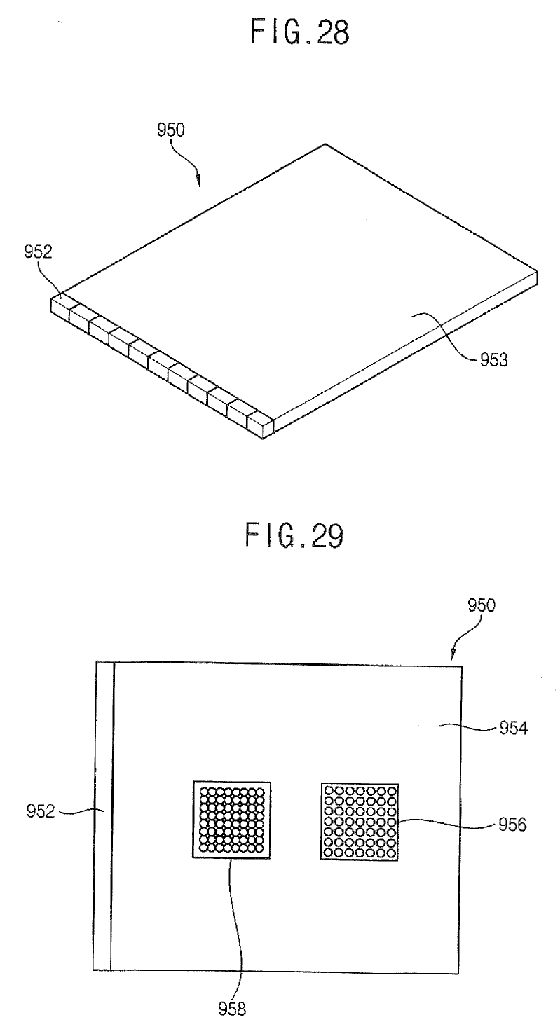

FIG. 28 is a perspective view illustrating a modular memory device in accordance with example embodiments. FIG. 29 is a cross-sectional view illustrating the modular memory device in FIG. 28.

Referring to FIGS. 28 and 29, the modular memory device 950 includes a connector 952 formed at an edge thereof and a housing 953.

The connector 952 has the structure of a conductive pad. A plurality of the connectors 952 are separated from each other by a predetermined distance. The distance between the adjacent connectors may correspond to distances between external connectors. The connector 952 may not be limited to an edge connector formed at an edge of the modular memory device 950.

When the housing 953 encloses the modular memory device 950, the housing 953 protects internal components of the modular memory device 950 to prevent the internal components from being damaged by external impacts. The modular memory device 950 enclosed by the housing 953 may be easily transferred by a user. The modular memory device 950 enclosed by the housing 953 may be a compact modular handheld unit, which may be easily inserted into or removed from a readable device such as a camera or an e-book reader.

The modular memory device 950 includes a printed circuit board (PCB) 954, a memory unit 956 and an interface unit 958.

The PCB 954 may be formed outside of the modular memory device 950. In some example embodiments, the PCB 954 supports the connector 952, the memory unit 956 and the interface unit 958.

The memory unit 956 may includes various structures of a memory array and a memory array controller described above. For example, the memory array may include the NAND flash memory array stricture or the NOR flash memory array structure.

In some example embodiments, the interface unit 958 may be formed to be separated from the memory unit 956. The interface unit 958 may be electrically connected to the memory unit 956 and the connector 952 through the PCB 954. The interface unit 958 and the memory unit 856 may be directly formed on the PCB 954. The interface unit 958 may include various elements generating a voltage and/or a clock frequency. The interface unit 958 may include various elements for the modular memory device 950 to be connected to or inserted into various devices used by the user.

According to some embodiments of the present invention, an active region includes an upper active region having a first width and a lower active region having a second width substantially larger than the first width. Thus, the capacitance of a tunnel insulation layer formed on the upper active region may be reduced, so that the coupling ratio of a memory device may be improved. Accordingly, the memory device may have improved electrical operation characteristics due to the improvement of the coupling ratio.

Additionally, the lower active region of the active region and an isolation layer may reduce interference between adjacent floating gates and/or reduce parasitic capacitance.

Further, the memory device may be manufactured by only adding simple processes. Thus, costs for manufacturing the memory device may not be largely increased.

In the drawings and specification, there have been disclosed typical embodiments of the invention and, although specific terms are employed, they are used in a generic and descriptive sense only and not for purposes of limitation, the scope of the invention being set forth in the following claims.

1. A non-volatile memory device comprising:
a substrate;
an active region in the substrate, the active region including an upper active region having a first width and a lower active region beneath the upper active region and having a second width substantially larger than the first width;
an isolation layer adjacent to the active region;
a tunnel insulation layer on the upper active region;
a floating gate on the tunnel insulation layer and having a third width substantially larger than the first width;
a dielectric layer on the floating layer; and
a control gate on the dielectric layer.

2. The non-volatile memory of claim 1, wherein a thickness of the upper active region and a thickness of the lower active region have a ratio of about 0.05:1 to about 0.5:1.

3. The non-volatile memory of claim 1, wherein the isolation layer comprises:
a first isolation layer that extends from the floating gate to the lower active region; and
a second isolation layer that is disposed on a sidewall of the upper active region between the first isolation layer and the upper active region.

4. The non-volatile memory of claim 3, wherein an upper face of the floating gate opposite the substrate and an upper face of the first isolation layer opposite the substrate are disposed at substantially the same level.

5. The non-volatile memory of claim 3, wherein an upper face of the floating gate opposite the substrate is disposed at a level substantially higher relative to the substrate than an upper face of the first isolation layer.

6. The non-volatile memory of claim 3, wherein a difference between the first width and the second width corresponds to the thickness of the second isolation layer.

7. The non-volatile memory of claim 1, the dielectric layer includes a material having a high dielectric constant.

8. The non-volatile memory of claim 7, the dielectric layer includes tantalum oxide (Ta2O5), titanium oxide (TiO2), hafnium oxide (HfO2), zirconium oxide (ZrO2), hafnium silicate (HfSixOy), zirconium silicate (ZrSixOy), hafium silicon oxynitride (HfSixOyNz), zirconium silicon oxynitride (ZrSixOyNz), aluminum oxide (Al2O3), aluminum oxynitride (AlxOyNz), hafnium aluminate (HfAlxOy), yttrium oxide (Y2O3), niobium oxide (Nb2O5), cesium oxide (CeO2), indium oxide (InO3), lanthanum oxide (LaO2), strontium titanate (STO, SrTiO3), lead titanate (PbTiO3), strontium ruthenium oxide (SrRuO3), and/or calcium ruthenium oxide (CaRuO3).

9. The non-volatile memory of claim 1, wherein the dielectric layer includes a composite layer in which an oxide layer, a nitride layer and an oxide layer are sequentially stacked.

10-20. (canceled)
